(19) United States
(12) Patent Application Publication
(10) Pub. No.: US 2021/0054497 A1
(43) Pub. Date: Feb. 25, 2021

(54) SYSTEMS AND METHODS FOR A LIFT AND ROTATE WAFER HANDLING PROCESS

(71) Applicant: OEM Group, LLC, Gilbert, AZ (US)

(72) Inventors: Marc A. Lariviere, Gilbert, AZ (US); Brendan V. Trang, Gilbert, AZ (US); Michael S. Correra, Gilbert, AZ (US); Christian K. Forgey, Gilbert, AZ (US); Juan M. Rios Reyes, Gilbert, AZ (US)

(73) Assignee: OEM Group, LLC, Gilbert, AZ (US)

(21) Appl. No.: 16/997,761

(22) Filed: Aug. 19, 2020

Related U.S. Application Data
(60) Provisional application No. 62/888,735, filed on Aug. 19, 2019.

(51) Int. Cl. C23C 14/50; H01L 21/67; H01L 21/687; C23C 14/35

(52) U.S. Cl. CPC C23C 14/50; H01L 21/67103; C23C 14/35; H01L 21/68742; H01L 21/68764; H01L 21/67259

(57) ABSTRACT

Various embodiments of a mechanical assembly for linear and rotational handling of electronic wafer substrates under high vacuum are disclosed herein.

### CROSS-REFERENCE TO RELATED APPLICATIONS

This is a non-provisional application that claims benefit to U.S. provisional application Ser. No. 62/888,735 filed on Aug. 19, 2019, which is herein incorporated by reference in its entirety.

### FIELD

The present disclosure generally relates to systems and methods for handling wafers during a sputtering process; and in particular, to a mechanical assembly for linear and rotational handling of a wafer substrate under high vacuum.

### BACKGROUND

The manufacturing of electronic substrates involves sputtering methods which may include the deposition of thin films and coatings of material on an atomic scale onto thin slices of semiconductor materials in a vacuum environment. These processes require high manufacturing standards to ensure compliance with requirements related to proper film coating thickness and uniformity. In the past, wafers have been held within a wafer processing chamber over a sputtering target or sputtering gun and remained stationary while particles were ejected at the wafer, causing issues with a lack of film uniformity across the wafer. These static arrangements also made wafer height adjustments for short or long throw sputtering cumbersome, as shield spacers must be manually replaced in order to alter wafer height. As such, a non-static method of wafer handling is desirable in order to meet the stringent standards of wafer manufacturing.

It is with these observations in mind, among others, that various aspects of the present disclosure were conceived and developed.

### BRIEF DESCRIPTION OF THE DRAWINGS

FIG. 1 is a perspective view of an embodiment of a wafer handling apparatus;

FIG. 2 is a cross-sectional view of an existing sputtering apparatus engaged with the wafer handling apparatus of FIG. 1 showing how the wafer handling apparatus affixes to a sputtering chamber;

FIGS. 3A and 3B are respective frontal views of the wafer handling apparatus of FIG. 1, respectively, showing the wafer handling apparatus in a “wafer loading” position (FIG. 3A) and a “wafer processing” position (FIG. 3B);

FIGS. 4A and 4B are respective side views of a pin assembly of the wafer handling apparatus of FIG. 1, respectively showing the pin assembly in a “wafer processing” (FIG. 4A) and “wafer loading” position (FIG. 4B);

FIG. 5 is an enlarged view of each of the pin assemblies for the wafer handling apparatus of FIG. 1;

FIGS. 6A and 6B are respective views of the pin assemblies of the wafer handling apparatus of FIG. 1 in a “wafer loading” position (FIG. 6A) and a “wafer processing” position (FIG. 6B) without the wafer present and FIGS. 6C and 6D are respective views of the pin assemblies of the water handling apparatus of FIG. 1 in a “wafer loading” position (FIG. 6C) and a “wafer processing” position (FIG. 6D) with the wafer present;

FIG. 7 is a perspective view of a second embodiment of the wafer handling apparatus;

FIG. 8 is a partially exploded front view of the wafer handling apparatus of FIG. 7;

FIG. 9 is a partially exploded view of a heated wafer chuck of the wafer handling apparatus of FIG. 7;

FIG. 10 is a side view of a gas assembly of the wafer handling apparatus of FIG. 7;

FIG. 11 is a front view of the gas assembly of FIG. 10;

FIG. 12 is a perspective view of the wafer handling apparatus of FIG. 7 with a vertical rod and the gas assembly removed;

FIG. 13 is an enlarged view taken along circle 13 of an exploded feedthrough of the wafer handling apparatus of FIG. 12;

FIG. 14A is a partially exploded side view of the wafer chuck of the wafer handling apparatus of FIG. 7 and a baseplate of a magnetron assembly; and

FIG. 14B is an assembled side view of the wafer chuck of the wafer handling apparatus of FIG. 7 and the baseplate of the magnetron assembly.

Corresponding reference characters indicate corresponding elements among the view of the drawings. The headings used in the figures do not limit the scope of the claims.

### DETAILED DESCRIPTION

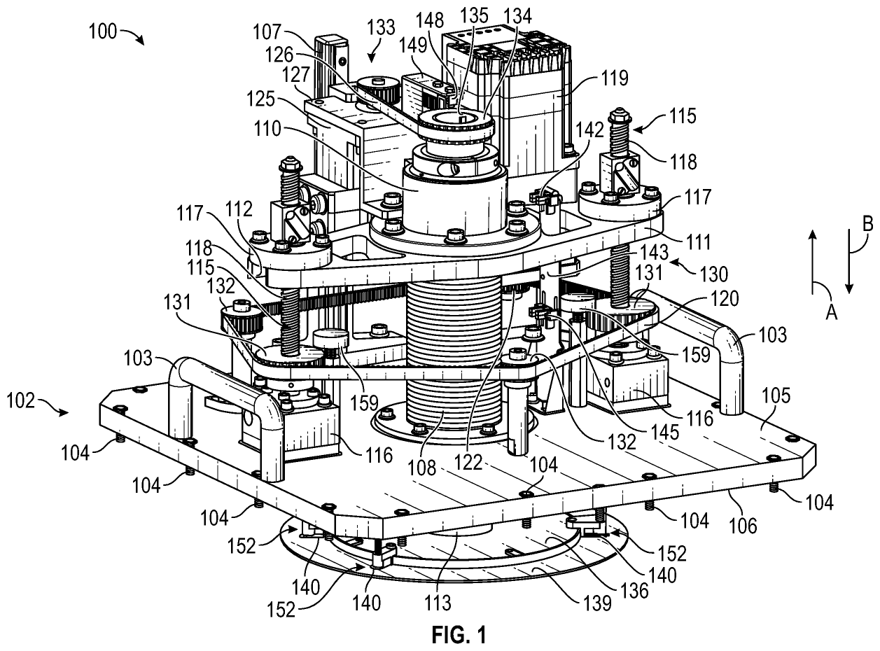

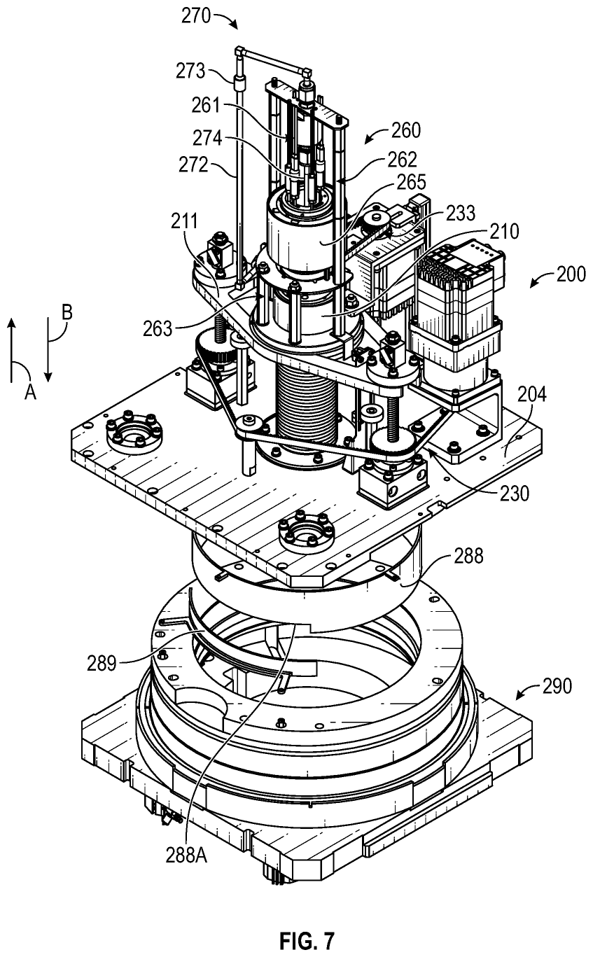

Various embodiments of a wafer handling apparatus are disclosed herein. In some embodiments, the wafer handling apparatus includes a wafer chuck associated with a vertical rod in which the vertical rod is operatively connected to two motors having respective pulley arrangements that actuate the vertical rod and the wafer chuck together in vertical and rotational movement. The wafer chuck is configured to engage a wafer to the underside of the wafer chuck for processing of the wafer within a wafer processing chamber. In some embodiments, a main plate of the wafer handling apparatus may be positioned above a wafer processing chamber such that particles ejected from a sputtering target contact the wafer engaged with the wafer chuck while the wafer chuck and wafer are in rotational or vertical motion, thereby allowing for even deposition of the particles along the wafer. In one aspect, the wafer handling apparatus may be retrofitted onto a conventional sputtering apparatus for processing a wafer engaged to the wafer chuck. Referring to the drawings, embodiments of the wafer handling apparatus are illustrated and generally indicated as 100 in FIGS. 1-6 and 200 in FIGS. 7-14.

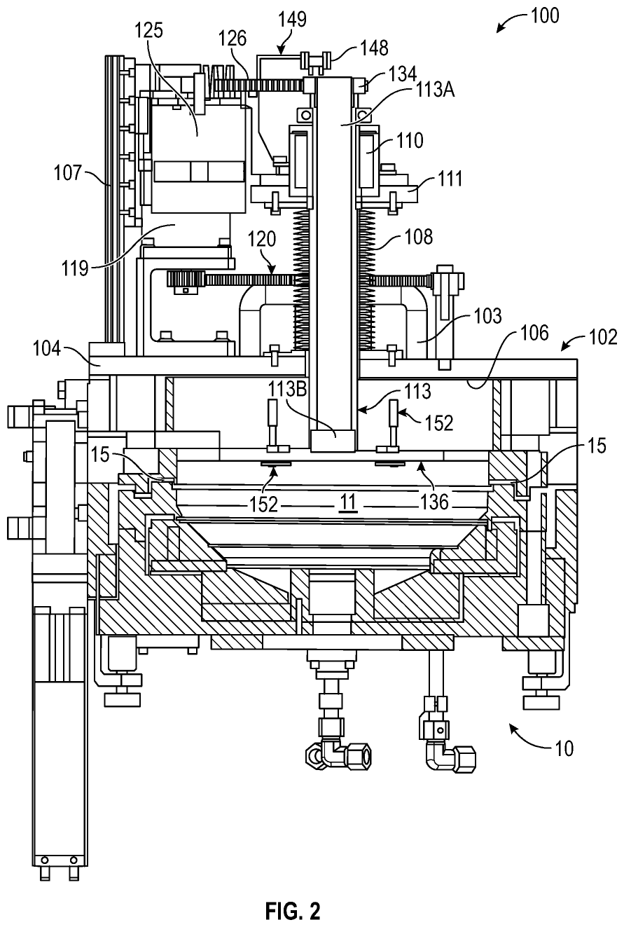

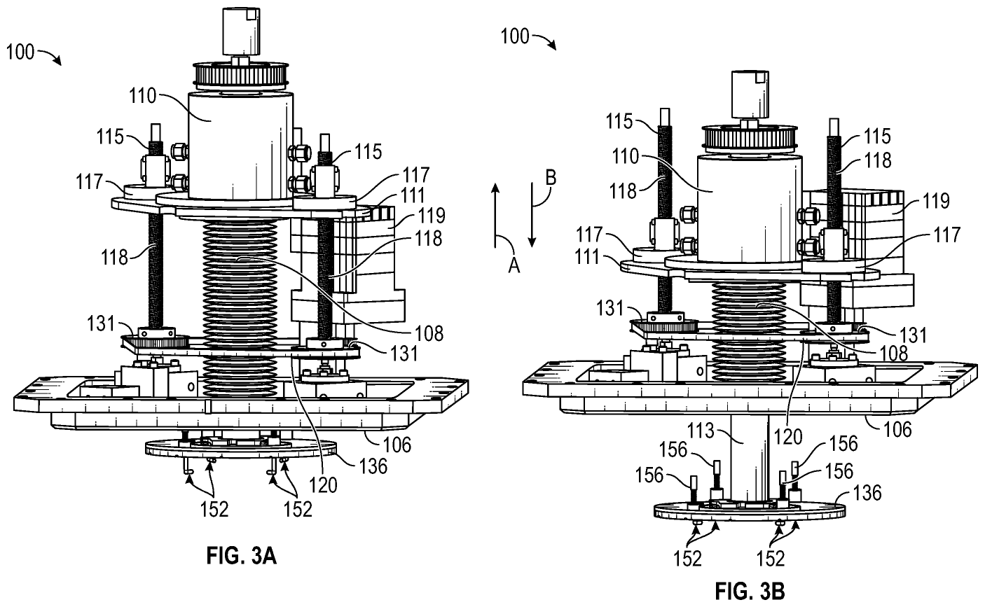

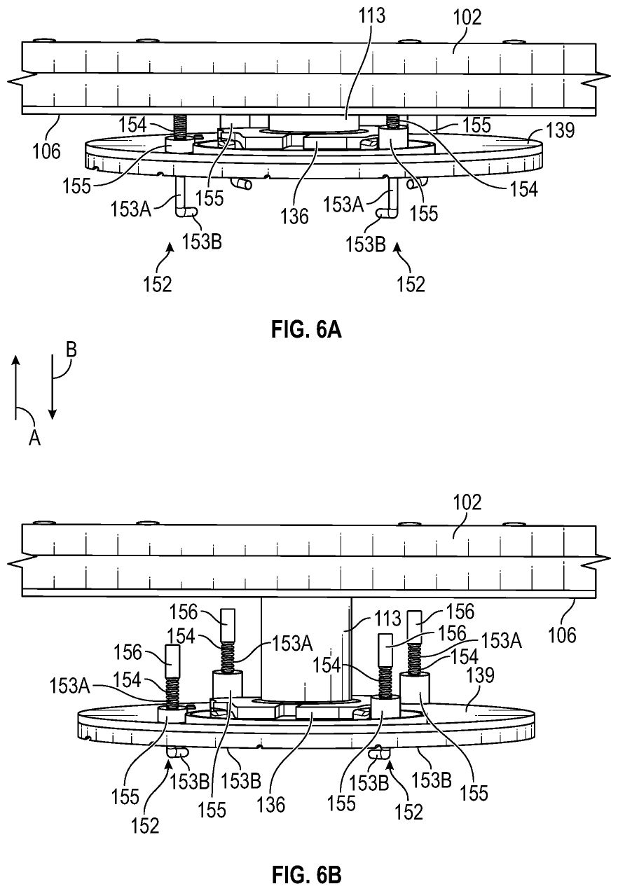

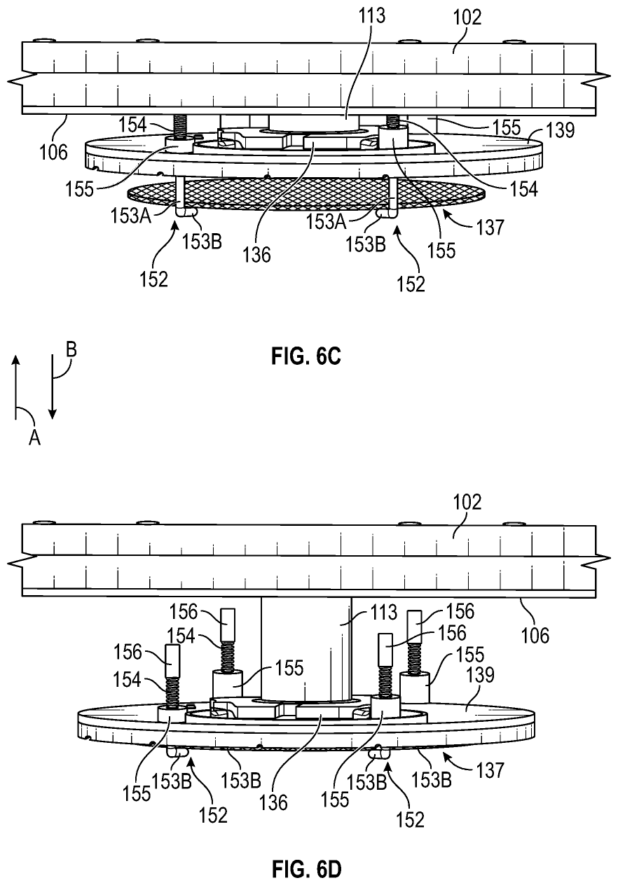

Referring to FIGS. 1-3, in some embodiments the wafer handling apparatus 100 is operable to engage, rotate, and lift a wafer 137 (FIGS. 6C and 6D) over a sputtering apparatus 10 (FIG. 2). The wafer handling apparatus 100 includes a wafer chuck 136 located underneath a main plate 102 and in operative association with a vertical rod 113 defining a first end 113A (FIG. 2) and a second end 113B (FIG. 2), the wafer chuck 136 being defined at the second end 113B of the vertical rod 113 and operable to receive the wafer 137 for processing. The wafer chuck 136 is lifted and/or lowered by a lifting assembly 130 associated with the vertical rod 113 to lift and/or lower the wafer 137 into a “wafer loading” position or a “wafer processing” position. The wafer chuck 136 is also rotated in a clockwise or counterclockwise direction by a rotational assembly 133 associated with the vertical rod 113 to rotate the wafer 137 in a clockwise or counterclockwise direction such that the wafer 137 is evenly coated with material during the sputtering process. In one method, to receive or offload the wafer 137, the wafer chuck 136 is lifted in an axial direction A by the lifting assembly 130 into the “wafer loading” position, shown in FIG. 3A. To process the wafer 137, the wafer chuck 136 is lowered into a wafer processing chamber 11 (FIG. 2) in an opposite axial direction B by the lifting assembly 130 into a “wafer processing” position, shown in FIG. 3B. The wafer handling apparatus 100 further includes a plurality of pin assemblies 152 disposed around the wafer chuck 136 which are operable to open when the wafer chuck 136 is in the “wafer loading” position such that the wafer 137 can be inserted between the plurality of pin assemblies 152 and the wafer chuck 136, as shown in FIG. 6C. In the “wafer processing” position, the plurality of pin assemblies 152 are released such that the wafer 137 is clamped against an underside of the wafer chuck 136 for processing, as shown in FIG. 6D. Once the wafer 137 has been processed, the wafer chuck 136 is once again lifted in an axial direction A into the “wafer loading” position such that the plurality of pin assemblies 152 release the wafer 137 from engagement with the wafer chuck 136 and remain open in the “wafer loading” position to receive another wafer 137.

Referring to FIGS. 1 and 2, in some embodiments, the wafer handling apparatus 100 includes the main plate 102 that provides a structure for assembling the components of the wafer handling apparatus 100. In some embodiments the main plate 102 defines a planar surface with a pair of handles 103 extending from a top face 105 of the main plate 102 for manually transporting the wafer handling apparatus 100. Prior to operation, in some embodiments as shown in FIG. 2, the main plate 102 of the wafer handling apparatus 100 is engaged along a lip 15 of a sputtering apparatus 10 and in direct communication with a wafer processing chamber 11 to rest on top of the lip 15 of a sputtering apparatus 10. The main plate 102 is secured to the lip 15 of the sputtering apparatus 10 via a plurality of securing members 104. In one arrangement, the plurality of securing members 104 are placed equidistant from each other along the edge of the main plate 102, thereby affixing the main plate 102 of the wafer handling apparatus 100 to the lip 15 of the sputtering apparatus 10. An existing sputtering apparatus 10 may have its original lid (not shown) removed and be retrofitted with the wafer handling apparatus 100 in place of the original lid. In other embodiments, a sputtering apparatus 10 may be manufactured to be integral with the wafer handling apparatus 100.

Referring to FIGS. 3A and 3B, the wafer handling apparatus 100 lifts the wafer chuck 136 in the axial directions A and/or B by a lifting assembly 130. As shown, the wafer chuck 136 and vertical rod 113 are operatively associated with a feedthrough plate 111 positioned above the main plate 102, which can be lifted or lowered in the axial direction A or B by a pair of elongated screws 115 defined by the lifting assembly 130 as the pair of elongated screws 115 rotate in a clockwise or counterclockwise direction. The pair of elongated screws 115 are rotated by the lifting assembly 130, which is in turn rotated by a lifting motor 119. Further, each elongated screw 115 defines an external thread 118 for engagement with the feedthrough plate 111 by way of a pair of respective screw nuts 117, each screw nut 117 engaging with a respective external thread 118 of the elongated screw 115. As shown, the “wafer loading” position is shown in FIG. 3A, and the feedthrough plate 111 is at maximum height relative to the main plate 102. The “wafer processing” position is shown in FIG. 3B, and the feedthrough plate 111 is at a lower height than the “wafer loading” position relative to the main plate 102.

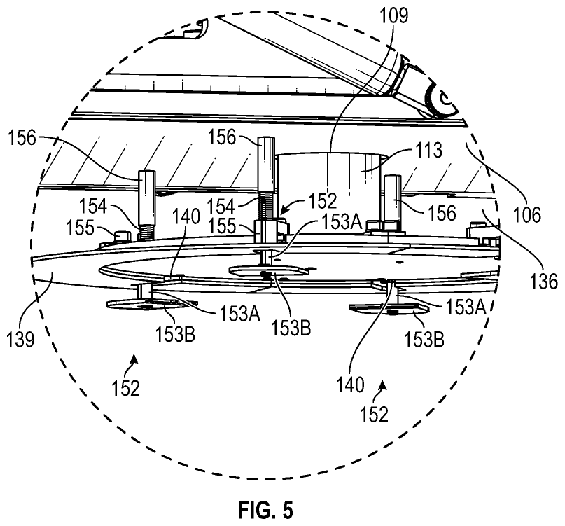

In some embodiments, the main plate 102 defines a main plate aperture 109 (FIG. 5) with a diameter greater than or equal to a diameter of the vertical rod 113 such that the vertical rod 113 can freely move in and out of the main plate aperture 109. As shown in FIG. 1, each elongated screw 115 is mounted to the top face 105 of the main plate 102 via a pair of respective screw mounts 116 located equidistant from the main plate aperture 109. The screw mounts 116 are affixed to the top face 105 of the main plate 102, while the elongated screws 115 are free to rotate in a clockwise or counterclockwise direction independent of the screw mounts 116. In some embodiments, a respective lift pulley 131 of the lifting assembly 130 is secured to each elongated screw 115 of the pair of elongated screws 115 such that when each lift pulley 131 is driven in a clockwise or counterclockwise direction, each respective elongated screw 115 is also driven in a clockwise or counterclockwise direction. As shown, a lift rail 107 (FIG. 1) may also be engaged the main plate 102 to provide support for other components of the wafer handling apparatus 100.

As shown in FIG. 1, in some embodiments the main plate 104 and lifting assembly 130 includes the lifting motor 119, which drives a lifting motor belt 120 engaged between the lifting motor 119 and the pair of lift pulleys 131. In some embodiments, a plurality of guide pulleys 132 are affixed to the top face 105 of the main plate 102 for retaining and guiding the lifting motor belt 120. In operation, the lifting motor 119 drives the lifting motor belt 120, which in turn drives the lift pulleys 131 affixed to each elongated screw 115, thereby rotating each of the elongated screws 115. The lifting motor 119 may include one or more lifting motor control ports (not shown) in which power, and in some embodiments, communication including controls and feedback with a computing system (not shown), may be applied.

As discussed above and as shown in FIG. 1, the feedthrough plate 111 is defined above the main plate 102 and can be lifted or lowered relative to the main plate 102 by the operation of the lift pulleys 131 and the elongated screws 115. The feedthrough plate 111 includes a pair of slots 112 with one slot 112 of the pair of slots 112 defined on each opposite side of the feedthrough plate 111 which are large enough for one of the respective elongated screw 115 to be inserted through. As discussed above, the feedthrough plate 111 is engaged with the external thread 118 of each elongated screw 115 via the pair of screw nuts 117. In particular, each screw nut 117 of the pair of screw nuts 117 is affixed to the feedthrough plate 111 and engaged with the external thread 118 of the elongated screw 115 such that as the pair of elongated screws 115 rotate, the feedthrough plate 111 follows the external thread 118 by the pair of screw nuts 117. As shown in FIG. 3A, as the pair of elongated screws 115 rotate in first clockwise or counterclockwise direction, the feedthrough plate 111 is lifted in an axial direction A relative to the main plate 102. Conversely, as shown in FIG. 3B, as the pair of elongated screws 115 rotate in an opposite second clockwise or counterclockwise direction, the feedthrough plate 111 is lowered in an axial direction B relative to the main plate 102.

In some embodiments and as discussed above, the vertical rod 113 is operatively coupled to the feedthrough plate 111. As the feedthrough plate 111 is lifted or lowered in either axial direction A or B by the pair of elongated ball screws 115 in operative association with the lift motor pulley 122 and the lift pulley arrangement 130, the vertical rod 113 is also lifted or lowered in either respective axial direction A or B relative to the main plate 102, as shown in FIGS. 3A and 3B. In some embodiments, a bellows 108 is included between an underside of the feedthrough plate 111 and the top face 105 of the main plate 102, thereby shielding the vertical rod 113. One or more stoppers 159 may be affixed to the top face 105 of the main plate 102 to prevent the feedthrough plate 111 from being lowered too far in an axial direction B.

Referring to FIG. 1, the wafer handling apparatus 100 rotates the wafer chuck 136 by the rotational assembly 133. As shown, the wafer chuck 136 and vertical rod 113 are operatively associated with the feedthrough plate 111 positioned above the main plate 102. The feedthrough plate 111 comprises a feedthrough 110 which receives the first end 113A of the vertical rod 113, the feedthrough 110 allows the vertical rod 113 to rotate freely within the feedthrough 110 while securing the first end 113A of the vertical rod 113 to the feedthrough plate 111. A rotational pulley 134 is rotated by a rotational motor 125 and operatively engaged with the first end 113A of the vertical rod 113 for clockwise or counterclockwise rotation of the vertical rod 113, which in turn rotates the wafer chuck 136 in a clockwise or counterclockwise direction.

As shown in FIG. 1, the rotational motor 125 which rotates the rotational pulley 134 is affixed to the feedthrough plate 111 via a rotational motor mount 127. The rotational motor 125 drives a rotational motor belt 126 engaged between the rotational motor 125 and the rotational pulley 134. In some embodiments, the rotational pulley 134 comprises an aperture 135 through its center such that a photoelectric sensor 148 can “look” down through the rotational pulley 134, vertical rod 113 and at the wafer 137 (FIGS. 6A and 6B) when engaged with the wafer chuck 136 to determine the presence of the wafer 137. The rotational motor 125 may have one or more rotational motor control ports (not shown) in which power, and in some embodiments, communication including controls and feedback with a computing system (not shown), may be applied.

As further shown in FIGS. 6A-6D, the second end 113B of the vertical rod 113 is operatively engaged with the wafer chuck 136. In some embodiments, an annular wafer shield 139 is defined around an outer edge of the wafer chuck 136. The wafer shield 139 defines a plurality of apertures 140 spaced equidistant from a center of the wafer chuck 136 such that the plurality of pin assemblies 152 are mounted along the edge of the wafer chuck 136 and each pin assembly 152 disposed through a respective one of the plurality of apertures 140 of the wafer shield 139. As shown in FIGS. 6C and 6D, the wafer chuck 136 and pin assemblies 152 are operable to engage the wafer 137 and clamp the wafer 137 to the underside of the wafer chuck 136 such that when the vertical rod 113 is moved in either axial direction A or B or rotated in a clockwise or counterclockwise direction, the wafer chuck 136 and wafer 137 are concurrently moved as well.

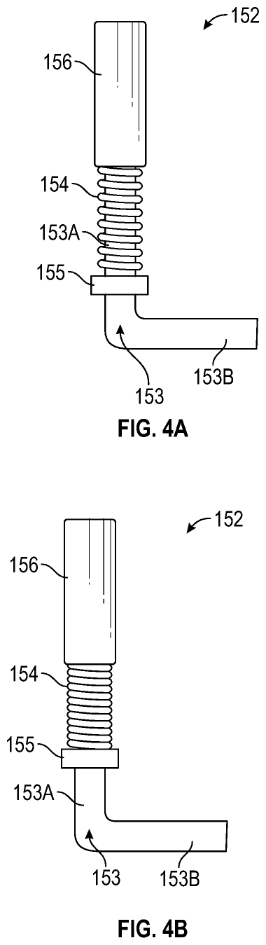

Referring to FIGS. 4A, 4B, 5, and 6A-6D, in some embodiments, the plurality of pin assemblies 152 include an “L”-shaped pin 153 including a vertical section 153A and a lateral section 153B. As shown specifically in FIGS. 6A and 6C, each vertical section 153A includes a pin cap 156 which, while in a “wafer loading” position, contacts an underside 106 of the main plate. Each pin assembly 152 is disposed through a respective securing piece 155, each securing piece 155 being engaged to a circumferential edge of the wafer chuck 136. In some embodiments, each vertical section 153A of the pin 153 is sheathed by a spring 154 located between the pin cap 156 and the securing piece 155, allowing each pin assembly 152 to clutch the wafer 137 against the underside of the wafer chuck while in the “wafer processing” position, as shown in FIGS. 6B and 6D. As shown in FIGS. 6A and 6C, when the vertical rod 113 and the wafer chuck 136 are lifted to the “wafer loading” position, each pin cap 156 contacts the underside 106 of the main plate 102 and compresses each spring 154 such that each respective pin 153 is lowered into the “wafer loading” position which maximizes a transfer gap between the lateral section 156 of each pin 152 and the underside of the wafer chuck 136 such that the wafer 137 may be inserted or removed. As shown in FIGS. 6B and 6D, the vertical rod 113 and wafer chuck 136 are lowered out of the loading position, the pin cap 156 no longer contacts the lower face 106 of the main plate 102 and each spring 154 will be allowed to assume a decompressed state and lift each pin 153 into a “wafer processing” position. In this “wafer processing” position, the wafer 137 is clamped in place to the underside of the wafer chuck 136 for processing by the lateral section 153B of each pin assembly 152.

Referring back to FIG. 1, in some embodiments, the wafer handling apparatus 100 includes one or more sensors for determining a presence of the wafer 137 (FIGS. 6A and 6B) engaged with the wafer chuck 136 and in some embodiments, for measurement of a height to which the wafer chuck 136 is lifted or lowered. In some embodiments, the photoelectric sensor 148 is mounted using a photoelectric sensor mounting bracket 149 positioned above the rotational pulley 134. In one embodiment, a line-of-sight of the photoelectric sensor 148 is aimed downward through the aperture 135 in the rotational pulley 134, the vertical rod 113, and/or an aperture 138 through the center of the wafer chuck 136 to determine if the wafer 137 is presently engaged with the wafer chuck 136. In the present disclosure, a sensor mounting bracket 143 is affixed to the top face 105 of the main plate 102 and disposed through a feedthrough plate aperture not shown). In some embodiments, an upper sensor 142 and a lower sensor 145 are mounted along the sensor mounting bracket 143, the upper sensor 142 being mounted at the top portion of the sensor mounting bracket 143 above the feedthrough plate 111 and the lower sensor 145 being mounted on the sensor mounting bracket 143 at variable height below the feedthrough plate 111. In one aspect, the upper sensor 142 and lower sensor 145 may be used to monitor the height of the feedthrough plate 111 to ensure that the feedthrough plate 111 does not exceed its maximum or minimum height and to otherwise ensure proper operation of the wafer handling apparatus 100.

In some embodiments the wafer handling apparatus 100 is operable to engage, rotate, and lift the wafer 137 within the sputtering apparatus 10 when the wafer handling apparatus 100 is operatively engaged to the sputtering apparatus 10. In some embodiments, the existing sputtering apparatus 10 may be retrofitted with the wafer handling apparatus 100 by removing the lid 17 (FIG. 2A) of the sputtering apparatus 10 and securing the wafer handling apparatus 100 to the lip 15 (FIG. 2B) of the sputtering apparatus 10 using the plurality of securing members 104. In other embodiments, a sputtering apparatus 10 may be designed to wholly integrate the wafer handling apparatus 100.

In one method of processing the wafer 137 using the wafer handling apparatus 100, the vertical rod 113 lifts the wafer chuck 136 to a maximum height relative to the main plate 102 into a “wafer loading” position by the lifting assembly 130 in conjunction with the pair of elongated ball screws 115. While in the “wafer loading” position, the plurality of pin assemblies 152 are operable to open and receive the wafer 137, as shown in FIGS. 3B, 6A and 6C. The vertical rod 113 lowers the wafer chuck 136 to a variable “wafer processing” position relative to the main plate 102 within the sputtering chamber 11 of the sputtering apparatus 10, as shown in FIGS. 3A and 5A. In this position, the plurality of pin assemblies 152 physically clamps the wafer 137 against an underside of the wafer chuck 136. The vertical rod 113 rotates the wafer chuck 136 and the wafer 137 by operation of the rotational assembly 133 such that the wafer 137 may be contacted by particles from the sputtering apparatus 10 while the wafer 137 is being rotated. Once the wafer 137 has been processed, the vertical rod 113 lifts and returns the wafer chuck 136 to the “wafer loading” position, where the plurality of pin assemblies 152 release the wafer and remain open and in position to receive another wafer 137.

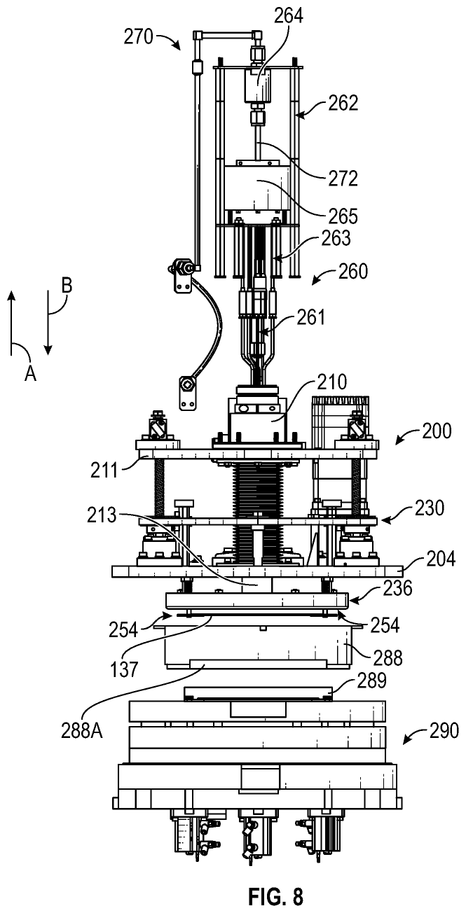

Referring to FIGS. 7 and 8, a second embodiment of the wafer handling apparatus 200 is shown including a wafer chuck 236, the wafer chuck 236 being defined at a lower end of a vertical rod 213 and operable to receive a wafer 137. As shown, the wafer handling apparatus 200 is similar to the wafer handling apparatus 100 including the vertical rod 213 in association with a feedthrough plate 211 by a feedthrough 210, a lifting assembly 230 for lifting or lowering the feedthrough plate 211 and consequently the heated wafer chuck 236 in an axial direction A or B relative to a main plate 204, and a rotational assembly 233 in communication with the feedthrough 210 and vertical rod 213 for rotation of the vertical rod 213 and heated wafer chuck 236. As discussed above, the lifting assembly 230, like the lifting assembly 130, is operable for lifting the wafer chuck 236 into a “wafer loading” position such that a plurality of pin assemblies 252 disposed around the wafer chuck 236 open and receive a wafer 137. The lifting assembly 230 is also operable for lowering the wafer chuck 236 into the “wafer processing” position such that the plurality of pin assemblies 252 secure the wafer 137 against an underside of the wafer chuck 236.

The wafer handling apparatus 200 further includes a thermoelectric assembly 260 and a gas assembly 270 in association with the feedthrough 210, vertical rod 213 and heated wafer chuck 236 for introducing power and gas to the heated wafer chuck 236. As shown, the wafer handling apparatus 200 is configured to be positioned above a baseplate 290 of a magnetron assembly for physical vapor deposition of material (not shown) onto the wafer 137. As shown, a shield 288 is included between the baseplate 290 of the magnetron assembly and the main plate 204 of the wafer handling apparatus 200.

As shown directly in FIGS. 7 and 8, the thermoelectric assembly 260 and the gas assembly 270 mounted to the feedthrough plate 211 by an upper frame 262 and a lower frame 263 for delivery of gas and power to the wafer chuck 236. Power delivery to the wafer chuck 236 is achieved through one or more power conduits 261 in electrical communication with the wafer chuck 236. In some embodiments the wafer chuck 236 may include one or more heating elements (not shown). The gas assembly 270 is shown in communication with the wafer chuck 236. The gas exits the wafer chuck 236 through a small aperture (not shown) defined on an underside of the wafer chuck 236 to provide uniformity of heat distribution to the wafer 137. As the rotational assembly 233 rotates the vertical rod 213 similar to the rotational assembly 133 of the wafer handling apparatus 100, a rotary union 264 and a slip ring 265 are respectively defined by the gas assembly 270 and the thermoelectric assembly 260 for preserving fluid flow communication of the gas assembly 270 with the wafer chuck 236 and preserving electrical communication of the one or more power conduits 261 with the wafer chuck 236.

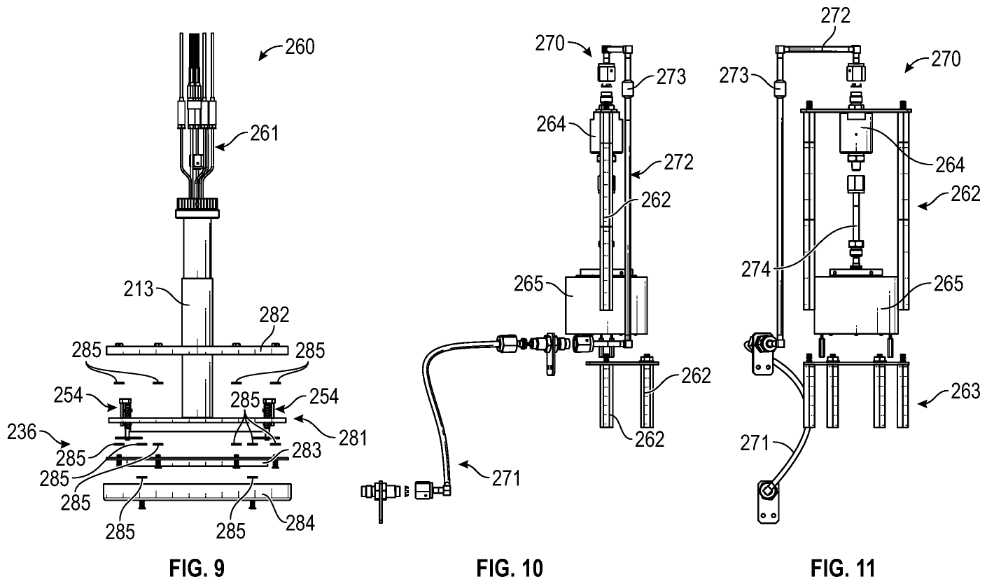

FIG. 9 illustrates the wafer chuck 236 defined at a lower end of the vertical rod 213. As shown, the wafer chuck 236 includes a wafer chuck component 281, similar to the wafer chuck 136 of the wafer handling assembly 100, which includes a plurality of pin assemblies 254 which are operable for receiving and securing the electronic wafer 137 against an underside of the wafer chuck component 281. In some embodiments, the wafer chuck 236 is in electrical communication with the thermoelectric assembly 260 for applying heat to the wafer 137, and may include one or more heating elements (not shown) for generating heat. As shown, the wafer chuck 236 further includes an upper shield 282 defined above the wafer chuck component 281, a lower shield 283 defined below the wafer chuck component 281, and an outer covering 284 which encapsulates the wafer chuck component 281, all which serve the purpose of conserving heat and directing heat towards the wafer chuck component 281 and consequently, the electronic wafer 137. The wafer chuck 236 further includes a plurality of spacers 285 for electrical and thermal insulation. In some embodiments each of the plurality of spacers 285 is of a thermally and electrically insulating material such as ceramic.

Referring to FIGS. 7, 9 and 11, the wafer chuck 237 is in electrical communication with the thermoelectric assembly 260, and in particular with the one or more power conduits 261 which may include one or more thermocouples and extend from the upper frame 262. As shown, the thermoelectric assembly 260 includes an electrical slip ring 265 for enabling electrical communication between the one or more power conduits 261 and the wafer chuck 236 while the vertical rod 213 and wafer chuck 236 are rotated independently of the upper frame 262. In some embodiments, the electrical slip ring 265 is supported above the feedthrough 210 by the lower frame 263.

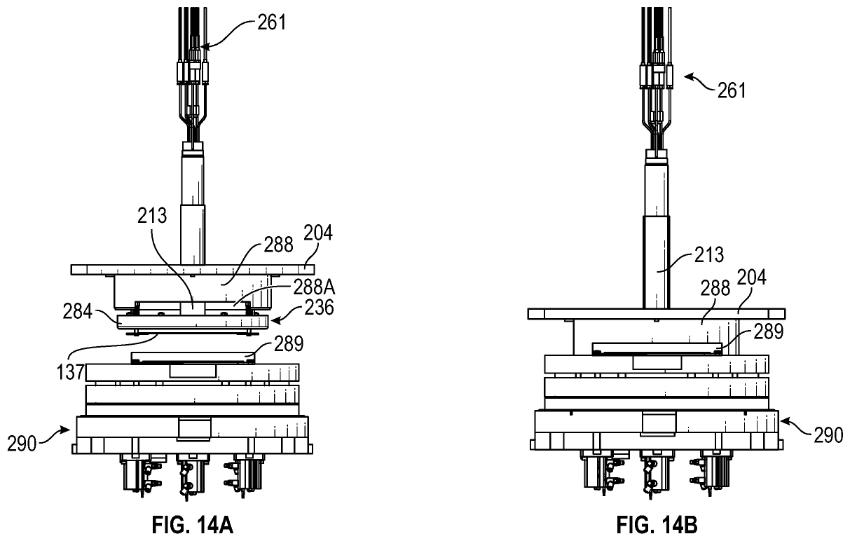

Referring directly to FIGS. 10 and 11, the gas assembly 270 comprises a gas inlet 271 in fluid flow communication with an external gas source (not shown) for introduction of a non-reactive gas, usually argon, for physical vapor deposition onto the wafer 137 (FIG. 14A). The gas inlet 271 transfers gas from the external source (not shown) to a gas line 272. In some embodiments, a cryogenic break 273 is included along the gas line 272 to provide a safety measure if the gas line 272 is broken or otherwise damaged. As shown, the gas line 272 terminates at a rotary union 264 for maintaining fluid flow communication to the heated chuck 236 while the heated chuck 236 and vertical rod 213 are rotated by the rotational assembly 233. The rotary union 264 and gas line 272 are supported above the feedthrough plate 211 by the upper frame 262. A secondary gas line 274 connects the rotary union 264 to the wafer chuck 236 and in some embodiments extends downward through the vertical rod 213 to terminate in the small aperture (not shown) defined on the underside (not shown) of the wafer chuck 236. The introduction of gas at the wafer chuck 236 while heat is concurrently applied to the wafer 137 allows for improved heat distribution uniformity across the wafer 137.

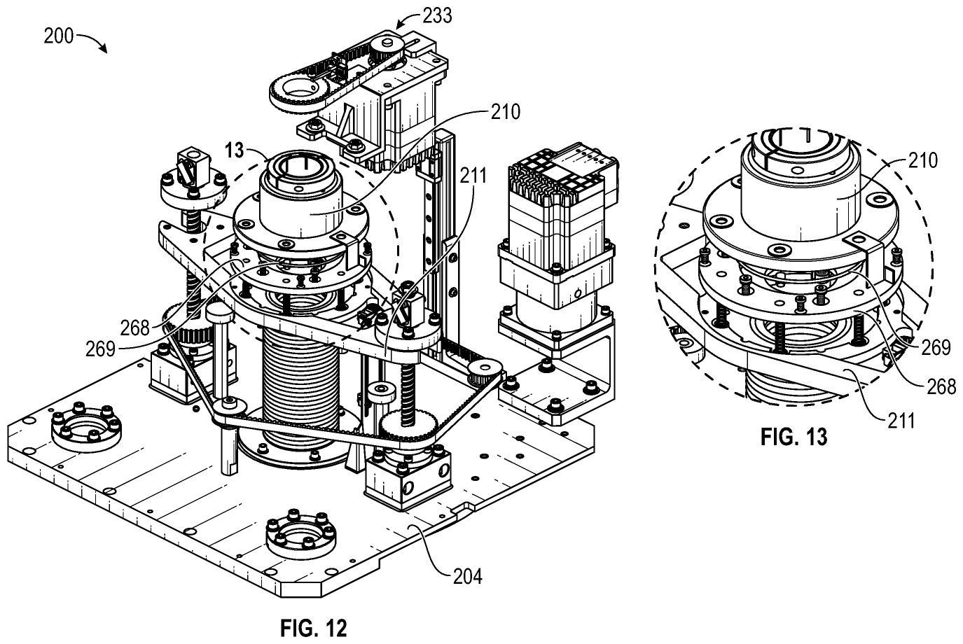

Referring to FIGS. 12 and 13, the feedthrough 210 is separated from the feedthrough plate 211 by an annular isolator 268. In some embodiments, the annular isolator 268 is an electrically insulating material such as Teflon. As shown, one or more O-rings 269 are included between the annular isolator 268 and the feedthrough 210 for ensuring an airtight connection between the gas assembly 270 (FIG. 11) and the wafer chuck 236.

Referring to FIGS. 14A and 14B, the wafer chuck 236 is disposed above the baseplate 290 of a magnetron assembly defining a wafer processing chamber. As shown, the shield 288 is secured underneath the main plate 204 of the wafer handling apparatus 200 and encapsulates the wafer chuck 236 such that an environment within the wafer processing chamber is controlled in terms of gas flow rate and pressure, as specifically shown in the assembled view of FIG. 14B. As shown, the shield 288 includes a slot 288A for insertion of a wafer 137 when in the “wafer loading” position. While in the “wafer processing” position, when the wafer 137 is being processed within the wafer processing chamber, the slot 288A is sealed by a slot guard 289 which is operable to move in and out of position to allow the wafer 137 to be inserted and removed when the wafer chuck 236 is in the “wafer loading” position and to seal the slot 288A when the wafer chuck 236 is in the “wafer processing” position.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A wafer handling apparatus, comprising:
a feedthrough plate in operative association with a first end of a vertical rod, wherein the feedthrough plate is operable to be lifted in an axial direction A to a wafer loading position and wherein the feedthrough plate is operable to be lowered in an opposite axial direction B to a wafer processing position;
a main plate defining a lower face and a main plate aperture, wherein the feedthrough plate is positioned above the main plate such that the vertical rod extends through the main plate aperture;
a wafer chuck coupled with a second end of the vertical rod and positioned below the main plate; and
a plurality of pin assemblies defined annularly around the wafer chuck, wherein each pin assembly of the plurality of pin assemblies comprises a lateral leg;
wherein when the feedthrough plate is lifted to the wafer loading position, a transfer gap between the wafer chuck and each lateral leg of each pin assembly of the plurality of pin assemblies is maximized such that an electronic wafer may be inserted between the wafer chuck and each lateral leg of each pin assembly of the plurality of pin assemblies; and
wherein when the feedthrough plate is lowered to the wafer processing position, a transfer gap between the wafer chuck and each lateral leg of each pin assembly of the plurality of pin assemblies is minimized such that the electronic wafer is secured to the wafer chuck by each lateral leg of each pin assembly of the plurality of pin assemblies.

2. The apparatus of claim 1, further comprising:
a lifting assembly in operative association with the feedthrough plate, the lifting assembly comprising:
a plurality of elongated screws, each elongated screw of the plurality of elongated screws defining an external thread and wherein each elongated screw of the plurality of elongated screws is operable for rotation about a vertical axis;
wherein each elongated screw of the plurality of elongated screws is coupled with a respective lift pulley of a plurality of lift pulleys such that when each lift pulley is driven in a clockwise or counterclockwise direction, each elongated screw of the plurality of elongated screws is rotated in a clockwise or counterclockwise direction; and
a lifting motor in operative association with each of the plurality of lift pulleys, wherein the lifting motor drives each lift pulley of the plurality of lift pulleys in a clockwise or counterclockwise direction;
wherein the external thread of each elongated screw of the plurality of elongated screws is operatively engaged with the feedthrough plate by a respective screw nut of the plurality of screw nuts such that as the plurality of elongated screws are rotated in a clockwise or counterclockwise direction, the feedthrough plate is lifted in the axial direction A or lowered in the axial direction B.

3. The apparatus of claim 1, further comprising:
a rotational assembly in operative association with the vertical rod, the rotational assembly comprising:
a rotational pulley coupled with the first end of the vertical rod, wherein when the rotational pulley is driven in a clockwise or counterclockwise direction, the vertical rod is rotated in a clockwise or counterclockwise direction; and
a rotational motor in operative association with the rotational pulley, wherein the rotational motor drives the rotational pulley in a clockwise or counterclockwise direction.

4. The apparatus of claim 1, wherein the pin assembly further comprises:
a pin defining an L-shaped body comprising a vertical leg and the lateral leg, the vertical leg comprising:
an upper portion and the lower portion, wherein the lateral leg extends from the lower portion of the vertical leg.

5. The apparatus of claim 4, further comprising:
a pin cap defined at the upper portion of the vertical leg; and
a spring sheathing the vertical leg such that the spring is positioned between the pin cap and the wafer chuck;
wherein the spring compresses between the pin cap and the wafer chuck such that the transfer gap between the wafer chuck and each lateral leg of each pin assembly of the plurality of pin assemblies is maximized; and
wherein the spring decompresses and pushes the pin cap away from the wafer chuck such that the transfer gap between the wafer chuck and each lateral leg of each pin assembly of the plurality of pin assemblies is minimized.

6. The apparatus of claim 5, wherein when the wafer chuck and the vertical rod are lifted to the wafer loading position, the pin cap contacts a lower face of the main plate and compresses the spring such that the transfer gap is maximized.

7. The apparatus of claim 6, wherein when the wafer chuck and the vertical rod are lowered to the wafer processing position, the pin cap separates from the lower face of the main plate and decompresses the spring such that the transfer gap is minimized.

8. The apparatus of claim 1, wherein the wafer chuck is operable to engage the wafer and dispose the wafer within a wafer processing chamber engaged to the wafer handling apparatus.

9. The wafer handling apparatus of claim 1, further comprising:
a photoelectric sensor operable for detecting the presence of the wafer; and
one or more sensors operable for detecting a vertical position of the feedthrough plate relative to the main plate;
wherein the photoelectric sensor and one or more sensors are in operative communication with a computing system for determining a vertical distance between the feedthrough plate and the main plate.

10. The wafer handling apparatus of claim 1, wherein the wafer chuck further comprises:
a thermoelectric assembly operable for applying heat to the wafer chuck.

11. The wafer handling apparatus of claim 1, further comprising:
a gas assembly in fluid flow communication with the wafer chuck, wherein the wafer chuck defines an aperture in fluid flow communication with the gas assembly such that a gas is released through the aperture of the wafer chuck.

12. The wafer handling apparatus of claim 1, further comprising a feedthrough, wherein the feedthrough is operatively engaged to the first end of the vertical rod and affixed to the feedthrough plate, and wherein the feedthrough enables rotation of the vertical rod independent of the feedthrough plate.

13. The wafer handling apparatus of claim 1, wherein the main plate is positioned above a wafer processing chamber such that the wafer chuck is disposed within the wafer processing chamber.

14. The wafer handling apparatus of claim 13, wherein the wafer handling apparatus further includes:
a shield encapsulating the wafer chuck within the wafer processing chamber.

15. The wafer handling apparatus of claim 14, wherein the shield further includes:
a wafer slot defined by the shield, the wafer slot including a slot guard operable for opening when the wafer chuck is in the wafer loading position and for sealing the wafer slot when the wafer chuck is in the wafer processing position.

16. A method for lifting and rotating a wafer using a wafer handling apparatus, comprising:
rotating each of a plurality of elongated screws having external threads in a clockwise or counterclockwise direction, wherein the plurality of elongated screws are in operative engagement with a feedthrough plate such that as each of the plurality of elongated screws rotate in a clockwise direction or a counterclockwise direction the feedthrough plate is lifted in an axial direction A or lowered in an axial direction B; and
rotating a vertical rod coupled to a wafer chuck in a clockwise direction or a counterclockwise direction, wherein the vertical rod is in operative engagement with the feedthrough plate such that when the feedthrough plate is lifted or lowered in opposing axial directions A or B, the vertical rod and wafer chuck are similarly lifted or lowered in opposing axial directions A or B.

17. The method of claim 16, wherein each of the plurality of elongated screws is rotated by a lifting assembly comprising a lifting pulley driven by a lifting motor.

18. The method of claim 16, wherein the feedthrough plate is operatively engaged to the external threads of each of the plurality of elongated screws using a respective screw nut, wherein each of the plurality of screw nuts comprise an internal threading in operative engagement with the external threads of the respective elongated screw and each of the plurality of screw nuts is affixed to a feedthrough plate.

19. The method of claim 16, wherein the elongated vertical rod is rotated by a rotational assembly comprising a rotational pulley driven by a rotational motor.

20. A method for receiving and securing a wafer using a wafer handling apparatus, comprising:
opening a pin assembly by lifting a wafer chuck in an axial direction such that a pin cap of the pin assembly contacts a lower face of a main plate and compresses a spring such that a pin of the pin assembly is lowered and a transfer gap between a lateral leg of the pin and the wafer chuck is maximized; and
closing the pin assembly by lowering the wafer chuck in an opposite axial direction such that the pin cap no longer contacts the lower face of the main plate and the spring assumes a decompressed position such that the pin is lifted and a transfer gap defined between the lateral leg of the wafer pin finger and the wafer chuck is minimized;
wherein a wafer may be inserted or removed when the pin assembly is open and the wafer may be secured to the wafer chuck when the pin assembly is closed.
